(19) United States
(12) Patent Application Publication
(10) Pub. No.: US 2014/0036249 A1
(43) Pub. Date: Feb. 6, 2014

(54) STAGE APPARATUS, LITHOGRAPHY APPARATUS, AND METHOD OF MANUFACTURING ARTICLE

(71) Applicant: CANON KABUSHIKI KAISHA, Tokyo (JP)

(72) Inventors: Hiroshi Kii, Utsunomiya-shi (JP); Nobushige Korenaga, Utsunomiya-shi (JP)

(73) Assignee: CANON KABUSHIKI KAISHA, Tokyo (JP)

(21) Appl. No.: 13/947,442

(22) Filed: Jul. 22, 2013

(30) Foreign Application Priority Data
Jul. 31, 2012 (JP) 2012-170373

(51) Int. Cl. G03F 7/20

(52) U.S. Cl. CPC G03F 7/70716
USPC 355/72; 355/77

(57) ABSTRACT

The preset invention provides a stage apparatus which holds a substrate, the apparatus including a driving unit which includes a first coil arranged on a fixed portion, and a first magnet which is arranged on a movable portion and opposed to the first coil, and is configured to move the movable portion by a magnetic field generated by supplying a current to the first coil, and an attracting unit which includes a first yoke arranged on the fixed portion, and a second coil wound around the first yoke, and is configured to attract the movable portion to a side of the fixed portion by a magnetic field generated by supplying a current to the second coil.

### BACKGROUND OF THE INVENTION

1. Field of the Invention

The present invention relates to a stage apparatus, a lithography apparatus, and a method of manufacturing an article.

2. Description of the Related Art

A lithography apparatus employed to manufacture a semiconductor device or a liquid crystal device performs a process (for example, exposure) of positioning a substrate held by a substrate stage to transfer a pattern onto the substrate. In the lithography apparatus, to keep up with miniaturization of the pattern to be transferred onto the substrate, the substrate stage is formed by a fine moving stage and coarse moving stage to attain highly accurate substrate positioning.

The fine moving stage which constitutes the substrate stage generally includes a fixed portion, a movable portion arranged on the fixed portion, and a linear motor serving as a driving unit which drives the movable portion, as disclosed in International Publication No. 2011/074962. The linear motor exhibits excellent response characteristics and vibration insulation properties, but disadvantageously generates a large amount of heat when it generates a force (that is, during its operation). Hence, the weights of the substrate and movable portion are supported by a spring element (elastic body) such as a coil spring without supporting them by the linear motor (without generating a force).

Also, a chuck which holds the substrate is mounted on the movable portion in the fine moving stage. Hence, when the substrate or chuck is removed from the movable portion in, for example, exchanging the substrate or chuck, the weights supported by the spring element decrease, so the movable portion ascends by the force of the spring element. Under the circumstance, in International Publication No. 2011/074962, a mechanical stopper for stopping the movement of the ascending movable portion by abutting against it (that is, for regulating its position in the Z-direction) is disposed on the fine moving stage. This is because heat generated by the linear motor becomes problematic when a force of the spring element that acts to lift the movable portion is canceled using, for example, the linear motor which drives the movable portion (that is, when a force which cancels that of the spring element which acts to lift the movable portion is generated by the linear motor).

Unfortunately, as in the conventional technique, when the movement of the movable portion is stopped by abutting it against the mechanical stopper, a play is set between the mechanical stopper and the movable portion, so the reproducibility of the attitude of the movable portion and, especially, its position in a rotation direction about the Z-axis (ωz-direction) degrades. In addition, wear of the mechanical stopper by repetitions of abutment of the movable portion leads to degradation in reproducibility of the attitude of the movable portion. As a result, it becomes difficult to accurately align the movable portion and chuck in mounting the chuck on the movable portion.

### SUMMARY OF THE INVENTION

The present invention provides a technique advantageous in controlling the position of a movable portion of a stage apparatus.

According to one aspect of the present invention, there is provided a stage apparatus which holds a substrate, the apparatus comprising: a fixed portion; a movable portion which is arranged on the fixed portion, and on which a substrate holder that holds the substrate is mounted; a driving unit which includes a first coil arranged on the fixed portion, and a first magnet which is arranged on the movable portion and opposed to the first coil, and is configured to move the movable portion by a magnetic field generated by supplying a current to the first coil; a spring element configured to support the movable portion to set the movable portion at a reference position while the substrate holder that holds the substrate is mounted on the movable portion; and an attracting unit which includes a first yoke arranged on the fixed portion, and a second coil wound around the first yoke, and is configured to attract the movable portion to a side of the fixed portion by a magnetic field generated by supplying a current to the second coil, wherein the attracting unit attracts the movable portion to the side of the fixed portion to set the movable portion at the reference position after at least one of the substrate and the substrate holder is removed from the movable portion.

Further features of the present invention will become apparent from the following description of exemplary embodiments with reference to the attached drawings.

### BRIEF DESCRIPTION OF THE DRAWINGS

FIG. 1 is a schematic view showing the configuration of a lithography apparatus according to an aspect of the present invention.

FIG. 2 is a schematic view showing the configuration of a fine moving stage of a stage apparatus in the lithography apparatus shown in FIG. 1.

### DESCRIPTION OF THE EMBODIMENTS

Preferred embodiments of the present invention will be described below with reference to the accompanying drawings. Note that the same reference numerals denote the same members throughout the drawings, and a repetitive description thereof will not be given.

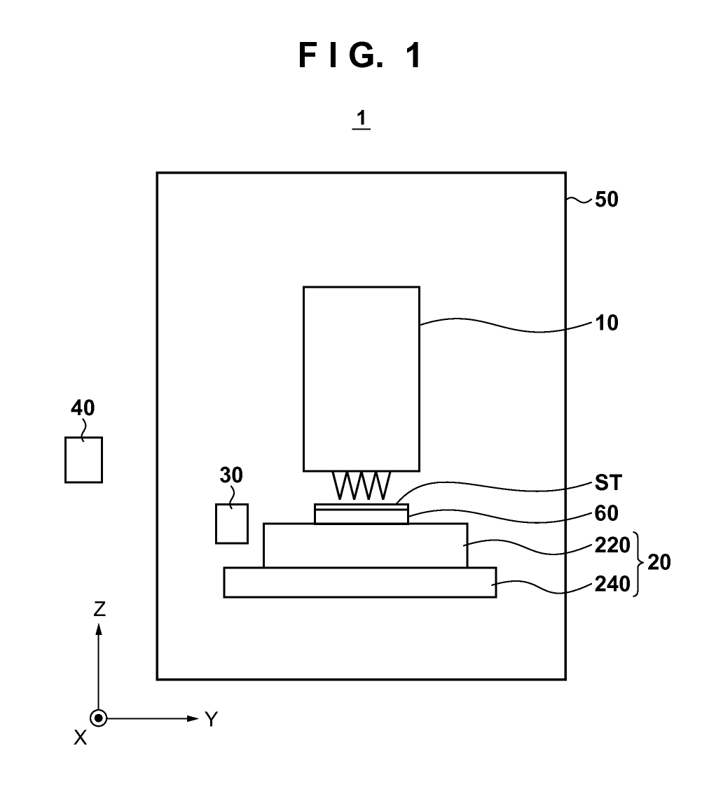

FIG. 1 is a schematic view showing the configuration of a lithography apparatus 1 according to an aspect of the present invention. The lithography apparatus 1 is an apparatus which transfers a pattern onto a substrate, and is actually used as a drawing apparatus which draws a pattern on a substrate with a charged particle beam (electron beam). However, the lithography apparatus 1 is not limited to a drawing apparatus, and may serve as an imprint apparatus or an exposure apparatus. The imprint apparatus means herein an apparatus which cures a resin on a substrate while a mold (die) is kept in contact with the resin, and separates the mold from the cured resin to transfer a pattern onto the substrate. Also, the exposure apparatus means an apparatus which projects and transfers the pattern of a reticle (mask) onto a substrate by a projection optical system.

The lithography apparatus 1 includes a charged particle optical system 10, a stage apparatus 20 which moves upon holding a substrate ST, a measuring unit 30, and a control unit 40. In the lithography apparatus 1, to draw a pattern with a charged particle beam in a vacuum atmosphere, the charged particle optical system 10, stage apparatus 20, and measuring unit 30 are placed in a vacuum chamber 50.

The charged particle optical system 10 includes, for example, a charged particle lens (electrostatic lens), collimator lens, aperture array, blanker array, stopping aperture array, and deflector. The charged particle optical system 10 guides a charged particle beam from a charged particle source (not shown) onto the substrate ST to draw a pattern on the substrate ST. With this arrangement, the charged particle optical system 10 has an aspect as a processing unit which performs a transfer process of transferring a pattern onto the substrate ST.

The stage apparatus 20 is formed by a fine moving stage 220 and coarse moving stage 240. The fine moving stage 220 has a function of correcting rotation of the substrate ST about the Z-axis, that of correcting the position of the substrate ST in the Z-direction, and that of correcting the tilt of the substrate ST. The fine moving stage 220 is arranged on the coarse moving stage 240 for positioning the substrate ST at a predetermined position in the X- and Y-directions. Also, the coarse moving stage 240 is mounted on a base (not shown).

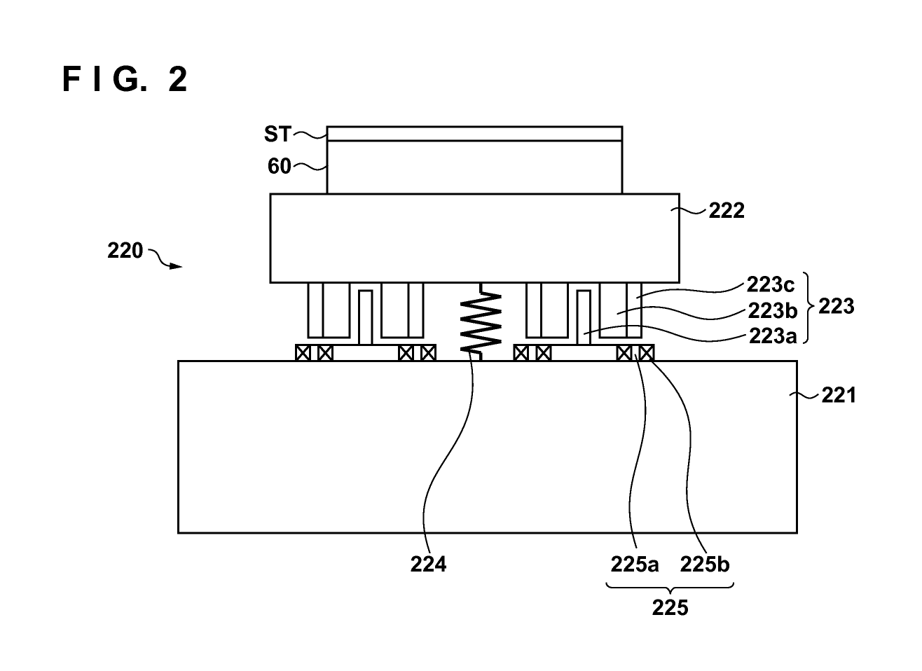

FIG. 2 is a schematic view showing the configuration of the fine moving stage 220. The fine moving stage 220 includes a fixed portion 221 fixed on the coarse moving stage 240, and a movable portion 222 which is arranged on the fixed portion 221, and on which a chuck 60 that functions as a substrate holder that holds the substrate ST is mounted. Also, the fine moving stage 220 includes a driving unit 223 which moves the movable portion 222, a spring element 224 which supports the movable portion 222, and an attracting unit 225 which attracts the movable portion 222 to the fixed portion side. Note that the movable portion 222 is equipped with a reference mirror (not shown) used in measuring the position of the movable portion 222.

The driving unit 223 includes a first coil 223a arranged on the fixed portion 221, a first magnet 223b which is arranged on the movable portion 222 and opposed to the first coil 223a, and a second yoke 223c arranged on the movable portion 222, together with the first magnet 223b. The driving unit 223 constitutes a linear motor which moves the movable portion 222 by a magnetic field generated by supplying a current to the first coil 223a. The lithography apparatus 1 allows six-axis position control of the movable portion 222 with respect to the fixed portion 221 via the driving unit 223 under the control of the control unit 40.

The spring element 224 is an elastic body which supports the movable portion 222 (substrate ST and chuck 60) to set the movable portion 222 at a reference position while the chuck 60 that holds the substrate ST (chucks it by suction) is mounted on the movable portion 222. The spring element 224 applies a force equal to the gravity (a force in the Z-direction) which acts on the movable portion 222, substrate ST, and chuck 60 to the movable portion 222. Therefore, in drawing a pattern on the substrate ST, the driving unit 223 need only perform position control of the movable portion 222, and need not support the movable portion 222, substrate ST, and chuck 60 (need not generate a force in the Z-direction), so heat generation can be suppressed.

The attracting unit 225 is provided separately from the driving unit 223, and includes a first yoke 225a arranged on the fixed portion 221, and a second coil 225b wound around the first yoke 225a. Although the first yoke 225a is opposed to the second yoke 223c in this embodiment, the present invention is not limited to this. The attracting unit 225 constitutes an electromagnet which attracts the movable portion 222 to the fixed portion side by a magnetic field generated by supplying a current to the second coil 225b. More specifically, the attracting unit 225 attracts the movable portion 222 to the fixed portion side to set the movable portion 222 at a reference position after at least one of the substrate ST and chuck 60 is removed from the movable portion 222.

Referring back to FIG. 1, the measuring unit 30 measures the position of the movable portion 222. The measuring unit 30 includes, for example, a laser interferometer which measures the position of the movable portion 222 in the X- and Y-directions using the reference mirror attached to the movable portion 222, and a capacitance sensor which measures the position of the movable portion 222 in the Z-direction.

The control unit 40 includes, for example, a CPU and memory, and controls the overall lithography apparatus 1 (its operation). In this embodiment, the control unit 40 controls the operations of the driving unit 223 and attracting unit 225. The control unit 40 operates only the driving unit 223 without operating the attracting unit 225 in positioning the movable portion 222 (that is, in drawing a pattern on the substrate ST) based on the position of the movable portion 222 measured by the measuring unit 30. On the other hand, the control unit 40 operates the attracting unit 225 in exchanging the substrate ST or chuck 60, that is, upon removing at least one of the substrate ST and chuck 60 from the movable portion 222 after an operation of drawing a pattern on the substrate ST ends.

At this time, the control unit 40 controls the operation of the driving unit 223 so as not to perform position control of the movable portion 222 in the Z-direction by the driving unit 223. However, position control of the movable portion 222 in the X- and Y-directions by the driving unit 223 may be done.

The operation of the lithography apparatus 1 and, especially, an operation of exchanging the substrate ST or chuck 60 will be described herein. This operation is performed by making the control unit 40 execute overall control of each unit (especially the driving unit 223 and attracting unit 225) of the lithography apparatus 1, as described above.

In the lithography apparatus 1, a charged particle beam is guided through the charged particle optical system 10 to the substrate ST held by the fine moving stage 220 (more specifically, the chuck 60 that holds the substrate ST is mounted on the movable portion 222) to draw a pattern on the substrate ST. At this time, the position of the movable portion 222 is measured by the measuring unit 30, and the control unit 40 operates the driving unit 223 based on the measurement result to position the movable portion 222 (the substrate ST mounted on it) at a predetermined position. The control unit 40 can operate the driving unit 223 by supplying a current to the first coil 223a. On the other hand, the control unit 40 does not operate the attracting unit 225 in drawing a pattern on the substrate ST.

After an operation of drawing a pattern on the substrate ST ends, the chuck 60 that holds the substrate ST (a substrate having a pattern drawn on it) is removed from the fine moving stage 220 (movable portion 222) by an exchange hand (not shown). At this time, the control unit 40 stops the operation of the driving unit 223, and operates the attracting unit 225. More specifically, in the attracting unit 225, a current is supplied to the second coil 225b to generate a force, equal to the gravity that acts on the substrate ST and chuck 60, between the first yoke 225a and the second yoke 223c. In other words, a force is generated by the attracting unit 225 to prevent the movable portion 222 from ascending, that is, to balance the generated force with that of the spring element 224 which acts to lift the movable portion 222, even when the substrate ST and chuck 60 are removed from the fine moving stage 220. With this arrangement, even when the substrate ST and chuck 60 are removed from the fine moving stage 220, the movable portion 222 can be set at a reference position while preventing the movable portion 222 from ascending. Note that the substrate ST and chuck 60 removed from the fine moving stage 220 are unloaded from the lithography apparatus 1 so as to be processed in subsequent steps.

The chuck 60 that holds a substrate ST on which a pattern is to be drawn (that is, a new substrate ST) is mounted on the fine moving stage 220 (movable portion 222) by the exchange hand (not shown). At this time, the control unit 40 stops the operation of the attracting unit 225. More specifically, the current supplied to the second coil 225b is set zero, so the force generated between the first yoke 225a and the second yoke 223c by the attracting unit 225 becomes zero. With this operation, the gravity that acts on the movable portion 222, substrate ST, and chuck 60 becomes equal to the force applied to the movable portion 222 by the spring element 224. Therefore, the movable portion 222 can be set at a reference position while preventing the movable portion 222 from descending when the substrate ST and chuck 60 are mounted on the fine moving stage 220. Also, the control unit 40 stops the operation of the attracting unit 225, and operates the driving unit 223 to start six-axis position control of the movable portion 222 based on the measurement result obtained by the measuring unit 30.

In this manner, the lithography apparatus 1 in this embodiment uses a force generated by the attracting unit 225 to cancel that of the spring element 224 which acts to lift the movable portion 222, after the substrate ST or chuck 60 is removed from the fine moving stage 220. With this operation, the lithography apparatus 1 can set the movable portion 222 at a reference position with high accuracy and high reproducibility without using, for example, a mechanical stopper. Therefore, the lithography apparatus 1 aligns the movable portion 222 and chuck 60 with high accuracy in mounting the chuck 60 on the movable portion 222.

Also, in this embodiment, in attracting the movable portion 222 to the fixed portion side by the attracting unit 225, the second yoke 223c is attracted (that is, the second yoke 223c is assumed to be attracted by the attracting unit 225). With this arrangement, a new object to be attracted by the attracting unit 225 need not be arranged on the movable portion 222, thus suppressing an increase in weight of the movable portion 222. This makes it possible to prevent an increase in amount of heat generated by the linear motor which constitutes the driving unit 223 without increasing the magnitude of the force of the driving unit 223, which is required in six-axis position control of the movable portion 222.

Furthermore, the amount of heat generation is sufficiently smaller when the electromagnet which constitutes the attracting unit 225 generates a force than when the linear motor which constitutes the driving unit 223 generates a force. Hence, the lithography apparatus 1 can keep the amount of heat generation relatively small, compared to the case wherein a force of the spring element 224 that acts to lift the movable portion 222 is canceled by that generated by the driving unit 223.

The lithography apparatus 1 in this embodiment can provide a high-quality article such as a semiconductor device, an LCD device, an image sensor (for example, a CCD), or a thin-film magnetic head with a high throughput and good economic efficiency. A method of manufacturing a device as an article includes a step of transferring a pattern on a substrate (a wafer, a glass plate, or a film-like substrate) using the lithography apparatus 1. The manufacturing method further includes steps of processing the substrate having the pattern transferred onto it (for example, oxidation, film formation, vapor deposition, doping, planarization, etching, resist removal, dicing, bonding, and packaging).

Also, for example, in this embodiment, the substrate ST and chuck 60 mounted on the movable portion 222 are exchanged every time an operation of drawing a pattern on the substrate ST ends. However, only the substrate ST may be exchanged without exchanging the chuck 60. In this case, the attracting unit 225 need only perform control to generate a force corresponding to the gravity that acts on the substrate ST.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-170373 filed on Jul. 31, 2012, which is hereby incorporated by reference herein in its entirety.

1. A stage apparatus which holds a substrate, the apparatus comprising:
a fixed portion;
a movable portion which is arranged on the fixed portion, and on which a substrate holder that holds the substrate is mounted;
a driving unit which includes a first coil arranged on the fixed portion, and a first magnet which is arranged on the movable portion and opposed to the first coil, and is configured to move the movable portion by a magnetic field generated by supplying a current to the first coil;
a spring element configured to support the movable portion to set the movable portion at a reference position while the substrate holder that holds the substrate is mounted on the movable portion; and
an attracting unit which includes a first yoke arranged on the fixed portion, and a second coil wound around the first yoke, and is configured to attract the movable portion to a side of the fixed portion by a magnetic field generated by supplying a current to the second coil,
wherein the attracting unit attracts the movable portion to the side of the fixed portion to set the movable portion at the reference position after at least one of the substrate and the substrate holder is removed from the movable portion.

2. The apparatus according to claim 1, further comprising:
a measuring unit configured to measure a position of the movable portion; and
a control unit configured to control an operation of the driving unit, and an operation of the attracting unit,
wherein the control unit
operates only the driving unit without operating the attracting unit in positioning the movable portion based on the position measured by the measuring unit, and
operated the attracting unit upon removing at least one of the substrate and the substrate holder from the movable portion.

3. The apparatus according to claim 1, wherein
the driving unit includes a second yoke arranged on the movable portion, together with the first magnet, and
the attracting unit attracts the second yoke by a magnetic field generated by supplying a current to the second coil.

4. A lithography apparatus comprising:
a stage apparatus configured to hold a substrate; and
a processing unit configured to perform a transfer process of transferring a pattern on the substrate held by the stage apparatus,
wherein the stage apparatus comprises:
a fixed portion;
a movable portion which is arranged on the fixed portion, and on which a substrate holder that holds the substrate is mounted;
a driving unit which includes a first coil arranged on the fixed portion, and a first magnet which is arranged on the movable portion and opposed to the first coil, and is configured to move the movable portion by a magnetic field generated by supplying a current to the first coil;
a spring element configured to support the movable portion to set the movable portion at a reference position while the substrate holder that holds the substrate is mounted on the movable portion; and
an attracting unit which includes a first yoke arranged on the fixed portion, and a second coil wound around the first yoke, and is configured to attract the movable portion to a side of the fixed portion by a magnetic field generated by supplying a current to the second coil,
wherein the attracting unit attracts the movable portion to the side of the fixed portion to set the movable portion at the reference position after at least one of the substrate and the substrate holder is removed from the movable portion.

5. The apparatus according to claim 4, wherein the transfer process includes a process of curing a resin on the substrate while a mold is kept in contact with the resin, and separating the mold from the cured resin to transfer the pattern onto the substrate.

6. The apparatus according to claim 4, wherein the transfer process includes a process of performing drawing on the substrate with a charged particle beam to transfer the pattern onto the substrate.

7. The apparatus according to claim 4, wherein the transfer process includes a process of projecting and transferring a pattern of a reticle onto the substrate by a projection optical system.

8. A method of manufacturing an article, the method comprising:
transferring a pattern on a substrate using a lithography apparatus; and
processing the substrate on which the pattern has been transferred,
wherein the lithography apparatus includes:
a stage apparatus configured to hold a substrate; and
a processing unit configured to perform a transfer process of transferring a pattern on the substrate held by the stage apparatus, and
the stage apparatus holds the substrate and includes:
a fixed portion;
a movable portion which is arranged on the fixed portion, and on which a substrate holder that holds the substrate is mounted;
a driving unit which includes a first coil arranged on the fixed portion, and a first magnet which is arranged on the movable portion and opposed to the first coil, and is configured to move the movable portion by a magnetic field generated by supplying a current to the first coil;
a spring element configured to support the movable portion to set the movable portion at a reference position while the substrate holder that holds the substrate is mounted on the movable portion; and
an attracting unit which includes a first yoke arranged on the fixed portion, and a second coil wound around the first yoke, and is configured to attract the movable portion to a side of the fixed portion by a magnetic field generated by supplying a current to the second coil,
wherein the attracting unit attracts the movable portion to the side of the fixed portion to set the movable portion at the reference position after at least one of the substrate and the substrate holder is removed from the movable portion.
